(19) United States
(12) Patent Application Publication
(10) Pub. No.: US 2009/0026596 A1
(43) Pub. Date: Jan. 29, 2009

(54) LEAD FRAME, SEMICONDUCTOR PACKAGE, AND STACKED SEMICONDUCTOR PACKAGE HAVING THE SAME

(75) Inventors: Sang-Wook PARK, Chungcheongnam-do (KR); Jong-Gi LEE, Gyeonggi-do (KR); Kun-Dae YEOM, Chungcheongnam-do (KR); Sung-Ki LEE, Chungcheongnam-do (KR); Ji-Seok HONG, Seoul (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 12/178,532

(22) Filed: Jul. 23, 2008

(30) Foreign Application Priority Data
Jul. 23, 2007 (KR) 2007-73339

(51) Int. Cl. H01L 23/495; H05K 7/18

(52) U.S. Cl. 257/676; 361/813; 257/E23.048

(57) ABSTRACT

In certain embodiments, a lead frame includes a paddle, a plurality of inner leads, first outer leads, and a second outer lead. The plurality of inner leads can be arranged at a side face of the paddle. The first outer leads can extend from the inner leads along a first direction and can be arranged at a substantially central portion of the side face of the paddle. Furthermore, each of the first outer leads can have a first area. The second outer lead can be arranged at an edge portion of the side face of the paddle and can be supported by the paddle. The second outer lead can have a second area that is larger than the first area.

### PRIORITY STATEMENT

This application claims priority under 35 U.S.C. §119 to Korean Patent Application No. 2007-73339, filed on Jul. 23, 2007, the contents of which are incorporated herein by reference in their entirety.

### SUMMARY

Exemplary embodiments of the disclosed technology include a lead frame, a semiconductor package, and a stacked semiconductor package. More particularly, certain embodiments of the disclosed technology include semiconductor packages that each has a lead frame that is electrically connected to a semiconductor chip. Certain embodiments further include a stacked semiconductor package that has multiple semiconductor packages that are stacked in a sequential manner.

Exemplary embodiments of the disclosed technology include a lead frame that is capable of suppressing breakage of an outermost lead. Certain embodiments also include semiconductor packages that each has a lead frame. Certain embodiments further include a stacked semiconductor package that has multiple semiconductor packages that are stacked in a sequential manner.

A lead frame in accordance with at least one aspect of the disclosed technology includes a paddle, inner leads, first outer leads, and at least one second outer lead. The inner leads are arranged at a side face of the paddle. The first outer leads extend from the inner leads in a first direction to be arranged at a substantially central portion of the side face of the paddle. Furthermore, each of the first outer leads has a first area. The second outer lead is arranged at an edge portion of the side face of the paddle to be supported by the paddle. The second outer lead has a second area that is larger than the first area.

According to certain embodiments of the disclosed technology, the second outer lead may be connected to the paddle via a sustaining lead.

According to certain embodiments of the disclosed technology, the second outer lead may have a length that is greater than the length of the first outer lead in the first direction. Furthermore, the second outer lead may have a first fixing groove that is formed at a long-side face of the second outer lead along a second direction that is substantially perpendicular to the first direction, so as to reinforce a fixing force of the second outer lead. The second outer lead may have a second fixing groove that is formed at a lower portion of an inner short-side face of the second outer lead in the first direction, so as to reinforce the fixing force of the second outer lead. Additionally, the second outer lead may have at least one dimple for enlarging the second area.

According to certain embodiments of the disclosed technology, the second outer lead may have a protruded portion from the paddle in the first direction that is shorter than the length of the first outer lead.

A semiconductor package in accordance with another aspect of the disclosed technology includes a lead frame, a semiconductor chip, conductive wires, and a molding member. The lead frame includes a paddle, inner leads, first outer leads, and at least one second outer lead. The inner leads are arranged at a side face of the paddle. The first outer leads extend from the inner leads in a first direction to be arranged at a substantially central portion of the side face of the paddle. Furthermore, each of the first outer leads has a first area. The second outer lead is arranged at an edge portion of the side face of the paddle to be supported by the paddle. The second outer lead has a second area that is larger than the first area. The semiconductor chip is placed on the paddle, and the conductive wires electrically connect the semiconductor chip to the inner leads. The molding member is formed on the semiconductor chip and the lead frame, so as to expose the first outer leads and the second outer lead.

According to certain embodiments of the disclosed technology, the lead frame may include a sustaining lead formed between the paddle and the second outer lead.

According to certain embodiments of the disclosed technology, the second outer lead may have a linear shape extending in the first direction. The first outer leads may have an upwardly bent shape.

According to certain embodiments of the disclosed technology, the second outer lead may have a first fixing groove that is formed at a long-side face of the second outer lead along a second direction that is substantially perpendicular to the first direction in order to receive the molding member, a second fixing groove formed at a lower portion of an inner short-side face of the second outer lead in the first direction in order to receive the molding member, and at least one dimple formed at a lower surface of the second outer lead.

A stacked semiconductor package in accordance with still another aspect of the disclosed technology includes a first semiconductor package, a second semiconductor package stacked on the first semiconductor package, and a conductive connecting member. The first semiconductor package includes a first semiconductor chip, a first lead frame, and a first molding member. The lead frame includes a paddle, first inner leads, first outer leads, and at least one second outer lead. The first semiconductor chip is placed on the paddle. The first inner leads are arranged at a side face of the paddle to be electrically connected with the first semiconductor chip. The first outer leads extend from the first inner leads in a first direction to be arranged at a substantially central portion of the side face of the paddle. Furthermore, each of the first outer leads has a first area. The second outer lead is arranged at an edge portion of the side face of the paddle in order to be supported by the paddle. The second outer lead has a second area that is larger than the first area. The second semiconductor package includes a second semiconductor chip, a second lead frame and a second molding member. The second lead frame is arranged on the first molding member in order to be electrically connected with the second semiconductor chip. The second molding member is formed on the second lead frame and the second semiconductor chip. The conductive connecting member electrically connects the first lead frame and the second lead frame with each other.

According to certain embodiments of the disclosed technology, the second outer lead may have a first fixing groove that is formed at a long-side face of the second outer lead along a second direction that is substantially perpendicular to the first direction in order to receive the first molding member, a second fixing groove that is formed at a lower portion of an inner short-side face of the second outer lead in the first direction in order to receive the first molding member, and at least one dimple formed at a lower surface of the second outer lead in order to receive the conductive connecting member.

According to certain embodiments of the disclosed technology, the second outer lead may have a linear shape extending in the first direction, and the first outer leads may have an upwardly bent shape. Furthermore, the conductive connecting member may be formed only between the first outer leads and the second lead frame in order to electrically insulate the second outer lead and the second lead frame from each other, for example.

According to the disclosed technology, the outermost arranged second outer lead may have an area that is larger than that of the first outer lead so that the second outer lead may have a strong resistivity against the cracks, for example. As a result, breakage of the second outer lead, which may be caused by cracks in the conductive connecting member, may be advantageously suppressed.

### BRIEF DESCRIPTION OF THE DRAWINGS

The above and other features and advantages of the disclosed technology will become more apparent by describing in detail exemplary embodiments thereof with reference to the accompanying drawings.

FIG. 1 is a plan view illustrating a lead frame in accordance with certain embodiments of the disclosed technology.

FIG. 2 is an enlarged plan view of portion II in FIG. 1.

FIG. 3 is a cross-sectional view taken along line III-III′ in FIG. 1.

FIG. 4 is a perspective view illustrating a semiconductor package in accordance with certain embodiments of the disclosed technology.

FIG. 5 is a cross-sectional view taken along line V-V′ in FIG. 4.

FIG. 6 is a cross-sectional view taken along line VI-VI′ in FIG. 4.

FIG. 7 is a perspective view illustrating a stacked semiconductor package in accordance with certain embodiments of the disclosed technology.

FIG. 8 is a cross-sectional view taken along line VIII-VIII′ in FIG. 7.

FIG. 9 is a cross-sectional view taken along line IX-IX′ in FIG. 7.

### DETAILED DESCRIPTION OF THE INVENTION

The disclosed technology is described more fully hereinafter with reference to the accompanying drawings, in which exemplary embodiments of the disclosed technology are illustrated. The disclosed technology may, however, be embodied in many different forms and should not be construed as being limited to the exemplary embodiments set forth herein. Rather, these exemplary embodiments are provided so that the present disclosure will be more thorough and complete and will more fully convey the scope of the disclosed technology to those skilled in the art. In the drawings, the sizes and relative sizes of layers and regions may be exaggerated for reasons of clarity.

It will be understood that when an element or layer is referred to as being “on,” “connected to,” or “coupled to” another element or layer, it can be directly on, connected, or coupled to the other element or layer, or intervening elements or layers may be present. In contrast, when an element is referred to as being “directly on,” “directly connected to,” or “directly coupled to” another element or layer, it is to be understood that there are no intervening elements or layers present. Like numerals refer to like elements throughout the present application. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. Rather, these terms are generally used to distinguish one element, component, region, layer, or section from another region, layer or section. Thus, a first element, component, region, layer, or section as discussed herein could be termed a second element, component, region, layer, or section without departing from the teachings of the disclosed technology.

Spatially relative terms, such as “beneath,” “below,” “lower,” “above,” “upper,” and the like, may be used herein for ease of description to describe one element or feature's relationship to another element(s) or feature(s), as illustrated in the figures, for example. It is to be understood that such spatially relative terms are typically intended to encompass different orientations of the pertinent device in use or operation in addition to the orientation as depicted in the figures. For example, if the pertinent device in the figures is turned over, elements described as “below” or “beneath” other elements or features would then be oriented “above” the other elements or features. Thus, the exemplary term “below” can encompass both an orientation of above and below. The pertinent device may be otherwise oriented (e.g., rotated 90 degrees or at other orientations) and the spatially relative descriptors used herein thus interpreted accordingly.

The terminology used herein is primarily for the purpose of describing particular exemplary embodiments only and is not intended to be limiting of the disclosed technology. As used herein, the singular forms “a,” “an,” and “the” are intended to include the plural forms as well, unless the context clearly indicates otherwise. It will be further understood that the terms “comprises” and/or “comprising,” when used in this specification, generally specify the presence of stated features, integers, steps, operations, elements, and/or components, but do not necessarily preclude the presence or addition of one or more other features, integers, steps, operations, elements, components, and/or groups thereof.

Exemplary embodiments of the invention are described herein with reference to cross-sectional illustrations that are schematic illustrations of such embodiments (and intermediate structures) of the disclosed technology. As such, variations from the shapes of the illustrations as a result of manufacturing techniques and/or tolerances, for example, are to be expected. Thus, exemplary embodiments of the disclosed technology should not be construed as being limited to the particular shapes of regions illustrated herein but are to include deviations in shapes that result, for example, from manufacturing. For example, an implanted region illustrated as a rectangle will typically have rounded or curved features and/or a gradient of implant concentration at its edges rather than a binary change from an implanted to a non-implanted region. Likewise, a buried region formed by implantation may result in some implantation in the region between the buried region and the surface through which the implantation takes place. Thus, the regions illustrated in the figures are generally schematic in nature and their shapes are not necessarily intended to illustrate the actual shape of a corresponding region of a device and are also not intended to limit the scope of the disclosed technology.

Unless otherwise defined, all terms (including technical and scientific terms) used herein typically have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the disclosed technology will be explained in detail with reference to the accompanying drawings.

Lead Frame

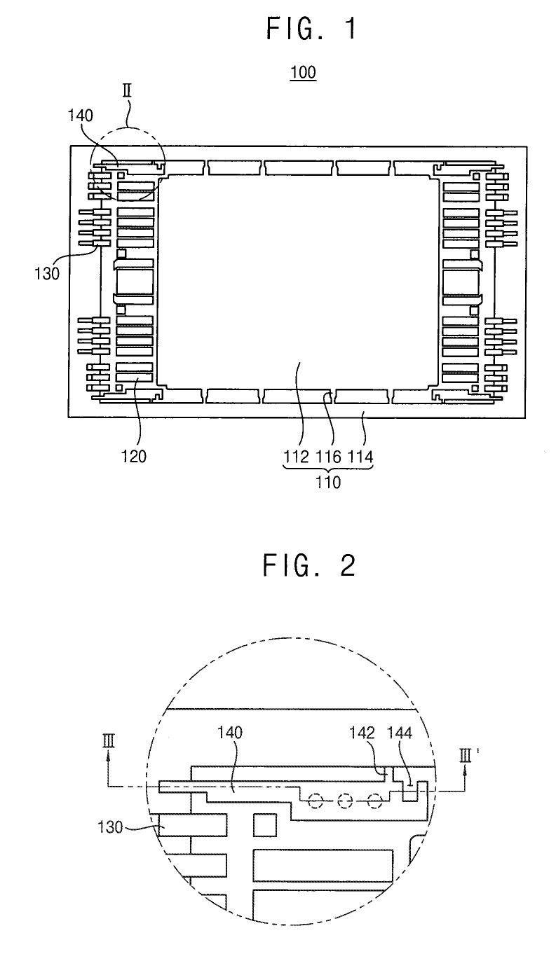

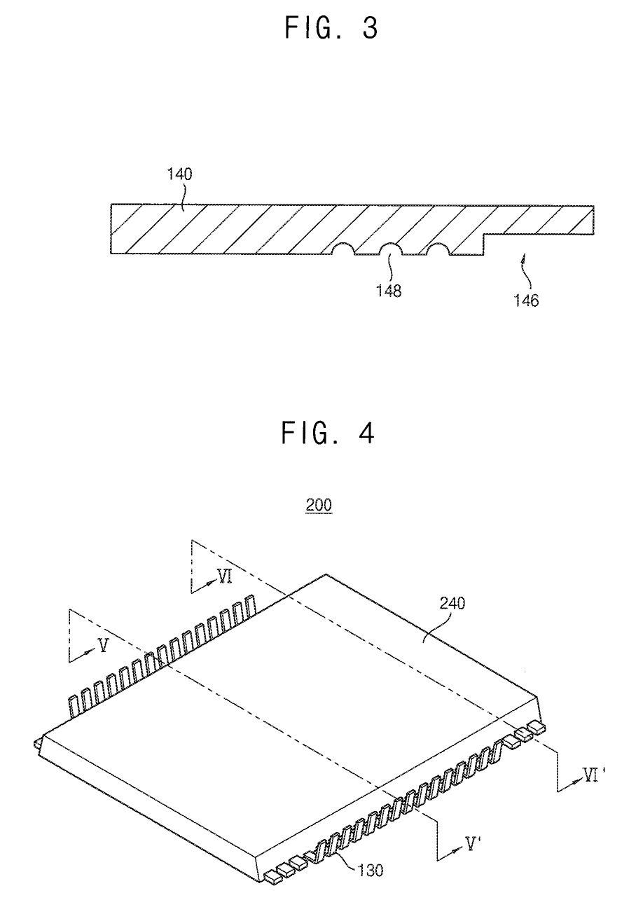

FIG. 1 is a plan view illustrating a lead frame in accordance with certain embodiments of the disclosed technology. FIG. 2 is an enlarged plan view of portion II in FIG. 1. FIG. 3 is a cross-sectional view taken along line III-III′ in FIG. 1.

Referring to FIGS. 1-3, an exemplary lead frame 100 includes a paddle 110, inner leads 120, first outer leads 130, and at least one second outer lead 140.

The paddle 110 includes a base plate 112, a side rail 114, and a tie bar 116. In the example, the base plate 112 may have a rectangular shape. A semiconductor chip (not shown) is placed on the base plate 112. The side rail 114 may have a rectangular frame shape configured to enclosing the base plate 112. A long-side of the base plate 112 may be connected to the side rail 114 via the tie bar 116.

The inner leads 120 are arranged adjacent to both short-side faces of the base plate 112. In the example, the inner leads 120 may have a long rectangular shape extending in a first direction. Furthermore, the inner leads 120 may be arranged in a second direction that is substantially perpendicular to the first direction. The inner leads are electrically connected to the semiconductor chip on the base plate 112.

The first outer leads 130 extend from the inner leads 120 in the first direction. In the example, the first outer leads 130 may be positioned at a substantially central portion of the base plate 112. Furthermore, each of the first outer leads 130 may have a first area.

The second outer lead 140 is arranged adjacent to edge portions of the short-side faces of the base plate 112. That is, the second outer lead 140 is placed adjacent to first outermost leads of the first outer leads 130. The second outer lead 140 is connected to the side rail 114 via a sustaining lead 142 in order to be supported by the side rail 114. Thus, if a crack is generated in the second outer lead 140, the second outer lead 140 is not easily broken because the side rail 114 connected to the second outer lead 140 via the sustaining lead 142 can firmly support the second outer lead 140. Furthermore, the second outer lead 140 may have a second area that is larger than the first area of each of the first outer leads 130. Therefore, since the second outer lead 140 has a relatively large second area, breakage of the second outer lead 140, such as could be caused by a crack, may be advantageously suppressed.

In the example, the second area of the second outer lead 140 may be substantially similar to a sum of the areas of the inner lead 120 and the first outer lead 130. Thus, the second outer lead 140 may have a length in the first direction that is greater than the length of each of the first outer leads 130.

The second outer lead 140 may be divided into an inner portion and an outer portion with respect to the sustaining lead 142. When a semiconductor package (not shown) is manufactured using the lead frame 100, the inner portion may be covered with a molding member (not shown). In contrast, the outer portion may be covered with a conductive connecting member (not shown) such as a solder member.

To firmly support the second outer lead 140 to the molding member, the second outer lead 140 has a first fixing groove 144 and a second fixing groove 146. The first fixing groove 144 and the second fixing groove 146 may be formed at the inner portion of the second outer lead 140. In the example, the first fixing groove 144 may be formed at an outer long-side face of the second outer lead 140 along the second direction. The molding member may be received in the first fixing groove 144 to prevent the second outer lead 140 from being released along the first direction. The second fixing groove 146 may be formed at a lower portion of an inner short-side face of the second outer lead 140 along the first direction. The molding member may be received in the second fixing groove 146 to prevent the second outer lead 140 from being inwardly bent along the first direction.

Furthermore, in order to provide the conductive connecting member on the second outer lead 140 with a desired thickness the second outer lead 140 can have a plurality of dimples 148. In the example, the dimples 148 may be formed at the outer portion of the second outer lead 140 in order to enlarge the second area of the second outer lead 140. The dimples 148 may be formed at a lower surface of the second outer lead 140. The conductive connecting member may surround the second outer lead 140 in order to fill up the dimples 148. Thus, the conductive connecting member may have the desired thickness due to the dimples 148.

In the example, the second outer lead 140 arranged adjacent to the outermost leads may have an area that is larger than that of the first outer lead. Thus, breakage of the second outer lead 140, such as could be caused by a crack, may be advantageously suppressed. Furthermore, the second outer lead 140 may be supported by the paddle 110 via the sustaining lead 142, so that the second outer lead may desirably not be broken. Since the molding member in the first fixing groove 144 and the second fixing groove 146 may firmly support the second outer lead 140, breakage of the second outer lead 140 may be even further suppressed. Moreover, the dimples 148 may serve to enlarge the area of the second outer lead 140 so that the conductive connecting member, having a sufficient thickness, may be formed on the second outer lead 140. As a result, spreading of the crack in the conductive connecting member may be advantageously delayed.

Semiconductor Package

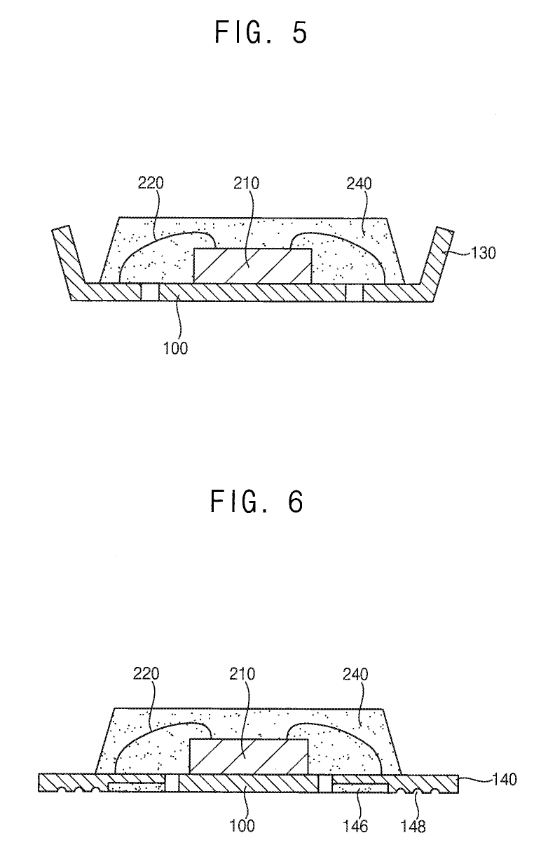

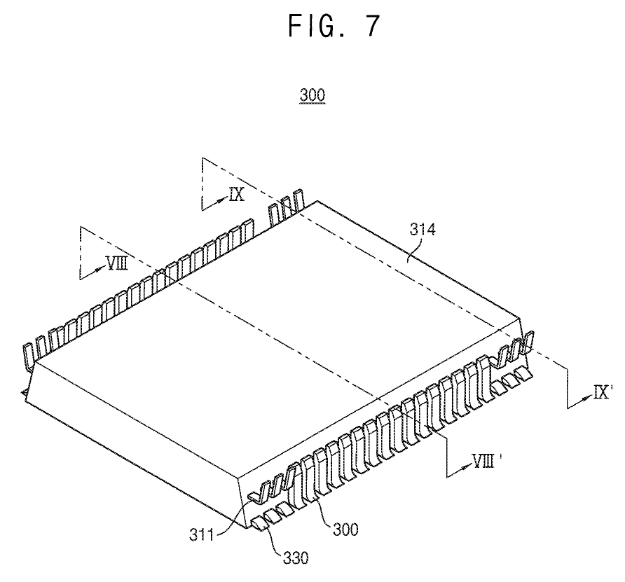

FIG. 4 is a perspective view illustrating a semiconductor package in accordance with certain embodiments of the disclosed technology. FIG. 5 is a cross-sectional view taken along line V-V′ in FIG. 4. FIG. 6 is a cross-sectional view taken along line VI-VI′ in FIG. 4.

Referring to FIGS. 4-6, an exemplary semiconductor package 200 includes a lead frame 100, a semiconductor chip 210, conductive wires 220, and a molding member 240.

The lead frame 100 includes elements that are substantially similar to those of the lead frame 100 illustrated in FIGS. 1-3. Thus, the same reference numerals used here refer to the same elements shown in FIGS. 1-3 and any further illustrations with respect to the same elements are omitted for reasons of brevity only.

The semiconductor chip 210 is placed on the paddle of the lead frame 100. The inner leads 120 of the lead frame 100 are electrically connected to bonding pads (not shown) of the semiconductor chip 210 via the conductive wires 220.

In the example, the first outer leads 130 may have an upwardly bent shape, (e.g., an “L” shape). The molding member 240 is formed on the lead frame 100 and the semiconductor chip 210 in order to expose the first outer leads 130.

In contrast, the second outer lead 140, having an area that is larger than that of the first outer leads 130, may have a linear shape extending in a horizontal direction. The first fixing groove (not shown) and the second fixing groove (not shown) of the second outer lead 140 are filled with the molding member 240. Therefore, the molding member 240 in the first fixing groove and the second fixing groove may firmly support the second outer lead 140.

Stacked Semiconductor Package

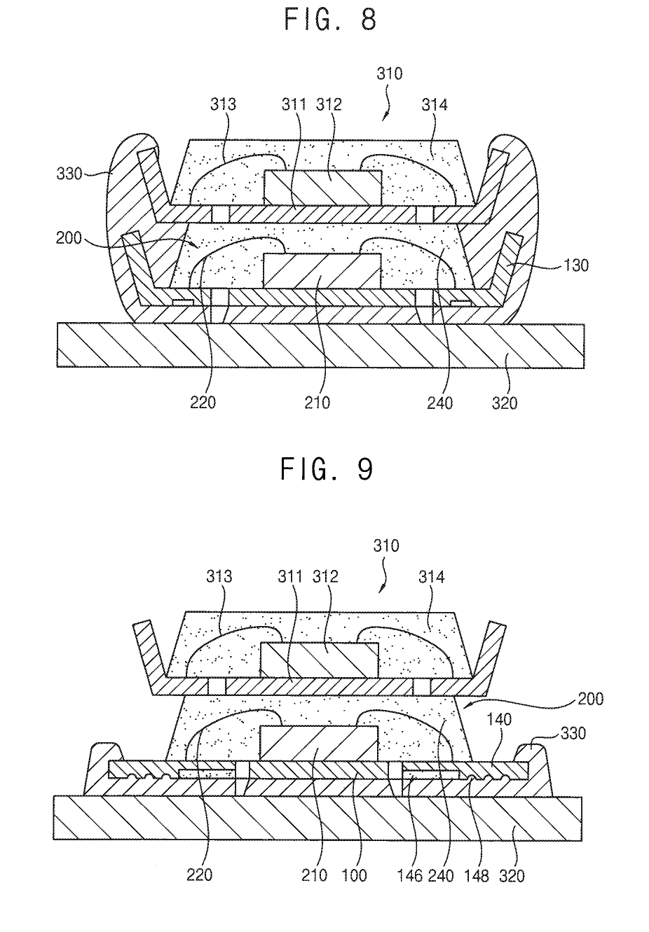

FIG. 7 is a perspective view illustrating a stacked semiconductor package in accordance with certain embodiments of the disclosed technology. FIG. 8 is a cross-sectional view taken along line VIII-VIII′ in FIG. 7. FIG. 9 is a cross-sectional view taken along line IX-IX′ in FIG. 7.

Referring to FIGS. 7-9, an exemplary stacked semiconductor package 300 includes a first semiconductor package 200, a second semiconductor package 310, a substrate 320, and conductive connecting members 330.

The first semiconductor package 200 includes elements that are substantially similar to those of the semiconductor package 200 illustrated in FIGS. 4-6. Thus, the same reference numerals used here refer to the same elements illustrated in FIGS. 4-6 and any further illustrations with respect to the same elements are omitted for reasons of brevity only.

The first semiconductor package 200 is stacked on the substrate 320. The second semiconductor package 310 is stacked on the first semiconductor package 200. In the example, the second semiconductor package 310 may include a second lead frame 311, a second semiconductor chip 312, second conductive wires 313, and a second molding member 314. The second semiconductor chip 312, the second conductive wires 313, and the second molding member 314 of the second semiconductor package 310 may be substantially similar to the first lead frame 100, the first semiconductor chip 210, the first conductive wires 220, and the first molding member 240 of the first semiconductor package 200, except for the second lead frame 311. Thus, any further illustrations with respect to the second semiconductor chip 312, the second conductive wires 313, and the second molding member 314 of the second semiconductor package 310 are omitted for reasons of brevity.

Outer leads of the second lead frame 311 may have substantially the same area. Furthermore, the outer leads of the second lead frame 311 may have an upwardly bent shape such as an “L” shape.

The conductive connecting members 330 may electrically connect the first outer leads 130 of the first semiconductor package 200 to the outer leads of the second semiconductor package 310. In contrast, the conductive connecting members 330 may surround only the linear second outer lead 140. Furthermore, the conductive connecting members 330 may not be formed on the outer lead of the second semiconductor package 310 that is located over the linear second outer lead 140. Thus, the second outer lead 140 of the first semiconductor package 200 may not be electrically coupled to the outer lead of the second semiconductor package 310. The second outer lead 140 of the first semiconductor package 200 may correspond to a dummy lead through which an electrical signal does not pass, so that it may not be necessary to electrically connect the second outer lead 140 with the outer lead of the second semiconductor package 310. As a result, the conductive connecting member 330 on an upper surface of the linear second outer lead 140 may have a sufficient thickness.

Furthermore, the conductive connecting members 330 may be received in the dimples 148 of the second outer lead 140. Thus, the conductive connecting members 330, having a sufficient thickness, may be formed on the second outer lead 140. As a result, spreading of a crack in the conductive connecting members 330 may be advantageously delayed.

According to certain embodiments of the disclosed technology, the second outer lead 140 may have the area that is larger than that of the first outer lead 130. Thus, breakage of the second outer lead 140, such as could be caused by a crack, may be advantageously suppressed.

Furthermore, the second outer lead 140 may be supported by the paddle via the sustaining lead, so that the second outer lead 140 may desirably not be broken.

Since the molding member in the first fixing groove and the second fixing groove may firmly support the second outer lead 140, breakage of the second outer lead 140 may be even further suppressed.

Moreover, the dimples 148 may serve to enlarge the area of the second outer lead 140 so that the conductive connecting member having a sufficient thickness may be formed on the second outer lead 140. As a result, spreading of a crack in the conductive connecting member may be advantageously delayed.

The foregoing is illustrative of the disclosed technology and is not to be construed as limiting thereof. Although a few exemplary embodiments of the disclosed technology have been described, those skilled in the art will readily appreciate that many modifications are possible in the exemplary embodiments without materially departing from the novel teachings and advantages of the disclosed technology. Accordingly, all such modifications are intended to be included within the scope of the disclosed technology as defined in the claims. In the claims, means-plus-function clauses are intended to cover the structures described herein as performing the recited function and not only structural equivalents but also equivalent structures. Therefore, it is to be understood that the foregoing is illustrative of the disclosed technology and is not to be construed as limited to the specific exemplary embodiments disclosed, and that modifications to the disclosed exemplary embodiments, as well as other exemplary embodiments, are intended to be included within the scope of the appended claims. The present invention is defined by the following claims, with equivalents of the claims to be included therein.

What is claimed is:

1. A lead frame comprising:
a paddle;
a plurality of inner leads arranged at a side face of the paddle;
first outer leads extending from the plurality of inner leads along a first direction, wherein the first outer leads are arranged at a substantially central portion of the side face of the paddle, and wherein each of the first outer leads has a first area; and
at least one second outer lead arranged at an edge portion of the side face of the paddle, wherein the at least one second outer lead is supported by the paddle, and wherein the second outer lead has a second area larger than the first area.

2. The lead frame of claim 1, further comprising a sustaining lead arranged between the second outer lead and the paddle.

3. The lead frame of claim 1, wherein the second outer lead has a length along the first direction greater than a length of the first outer leads.

4. The lead frame of claim 1, wherein the second outer lead has a first fixing groove that is formed at a long-side face of the second outer lead along a second direction, wherein the second direction is substantially perpendicular to the first direction.

5. The lead frame of claim 4, wherein the first fixing groove is formed at an outer long-side face of the second outer lead.

6. The lead frame of claim 1, wherein the second outer lead has a second fixing groove formed at an inner short-side face of the second outer lead along the first direction.

7. The lead frame of claim 6, wherein the second fixing groove extends from a lower portion of the inner short-side face of the second outer lead along the first direction.

8. The lead frame of claim 1, wherein the second outer lead has at least one dimple for enlarging the second area of the second outer lead.

9. The lead frame of claim 8, wherein the at least one dimple is formed at a lower surface of the second outer lead.

10. The lead frame of claim 1, wherein the second outer lead has a protruding portion extending from the paddle along the first direction, wherein the protruding portion has a length shorter than a length of the first outer lead.

11. The lead frame of claim 1, wherein the paddle comprises:
a base plate;
a side rail configured to surround the base plate, wherein the side rail is connected to the second outer lead; and
a tie bar connected between the side rail and the base plate.

12. A lead frame comprising:
a paddle;
a plurality of inner leads arranged at a side face of the paddle;
first outer leads extending from the plurality of inner leads along a first direction, wherein the first outer leads are arranged at a substantially central portion of the side face of the paddle, and wherein each of the first outer leads has a first area;
at least one second outer lead arranged at an edge portion of the side face of the paddle, wherein the at least one second outer lead is supported by the paddle, and wherein the second outer lead has a second area larger than the first area; and
a sustaining lead arranged between the second outer lead and the paddle,
wherein the second outer lead has a first fixing groove that is formed at a long-side face of the second outer lead along a second direction, wherein the second direction is substantially perpendicular to the first direction, a second fixing groove extending from a lower portion of an inner short-side face of the second outer lead along the first direction and at least one dimple formed at a lower surface of the second outer lead.

13. A semiconductor package comprising:
a lead frame comprising:
a paddle,
a plurality of inner leads arranged at a side face of the paddle,
first outer leads extending from the inner leads along a first direction, wherein the first outer leads are arranged at a substantially central portion of the side face of the paddle, each of the first outer leads having a first area, and
a second outer lead arranged at an edge portion of the side face of the paddle, wherein the second outer lead is supported by the paddle, and wherein the second outer lead has a second area that is larger than the first area;
a semiconductor chip placed on the paddle;
at least one conductive wire electrically connecting the semiconductor chip to the inner leads; and
a molding member that is formed on the semiconductor chip and the lead frame, wherein the molding member exposes the first outer leads and the second outer lead.

14. The semiconductor package of claim 13, wherein the lead frame further comprises a sustaining lead arranged between the second outer lead and the paddle.

15. The semiconductor package of claim 13, wherein the second outer lead has a linear shape extending along the first direction, and wherein the first outer leads have an upwardly bent shape.

16. The semiconductor package of claim 13, wherein the second outer lead comprises:
a first fixing groove that is formed at an outer long-side face of the second outer lead along a second direction, wherein the second direction is substantially perpendicular to the first direction, and wherein the first fixing groove receives the molding member;
a second fixing groove formed at an inner short-side face of the second outer lead along the first direction, wherein the second fixing groove receives the molding member; and
at least one dimple formed at a lower surface of the second outer lead.

17. A stacked semiconductor package comprising:
a first semiconductor package comprising a first semiconductor chip, a first lead frame electrically connected to the first semiconductor chip, and a first molding member formed on the first lead frame and the first semiconductor chip;
a second semiconductor package comprising a second semiconductor chip, a second lead frame electrically connected to the second semiconductor chip and arranged on the first molding member, and a second molding member formed on the second lead frame and the second semiconductor chip; and
at least one conductive connecting member electrically connecting the first lead frame to the second lead frame,
wherein the first lead frame comprises:
a paddle,
a plurality of inner leads arranged at a side face of the paddle,
first outer leads extending from the plurality of inner leads along a first direction, wherein the first outer leads are arranged at a substantially central portion of the side face of the paddle, and wherein each of the first outer leads has a first area, and
a second outer lead arranged at an edge portion of the side face of the paddle, wherein the second outer lead is supported by the paddle, and wherein the second outer lead has a second area that is larger than the first area.

18. The stacked semiconductor package of claim 17, wherein the lead frame further comprises a sustaining lead arranged between the second outer lead and the paddle.

19. The stacked semiconductor package of claim 17, wherein the second outer lead comprises:
a first fixing groove that is formed at an outer long-side face of the second outer lead along a second direction, wherein the second direction is substantially perpendicular to the first direction, and wherein the first fixing groove receives the first molding member;
a second fixing groove that is formed at an inner short-side face of the second outer lead along the first direction, wherein the second fixing groove receives the first molding member; and
at least one dimple formed at a lower surface of the second outer lead, wherein the at least one dimple receives the at least one conductive connecting member.

20. The stacked semiconductor package of claim 17, wherein the second outer lead has a linear shape extending along the first direction, wherein the first outer leads have an upwardly bent shape, and wherein the at least one conductive connecting member is formed between the first outer leads and the second lead frame.
